(19) United States
(12) Patent Application Publication
(10) Pub. No.: US 2026/0104460 A1
(43) Pub. Date: Apr. 16, 2026

(54) PREDICTION OF LIFESPAN OF A BATTERY USING MACHINE LEARNING MODEL

(71) Applicants: Irving A. Duran, Dubuque, IA (US); Aditya Bhushan Sharma, Faridabad (IN); Gideon Sireling, Jerusalem (IL); MATTHEW ALZAMORA, Poughkeepsie, NY (US)

(72) Inventors: Irving A. Duran, Dubuque, IA (US); Aditya Bhushan Sharma, Faridabad (IN); Gideon Sireling, Jerusalem (IL); MATTHEW ALZAMORA, Poughkeepsie, NY (US)

(21) Appl. No.: 18/916,266

(22) Filed: Oct. 15, 2024

(51) Int. Cl. G01R 31/367; G01R 31/3835; G01R 31/392; G01R 31/396

(52) U.S. Cl. CPC G01R 31/367; G01R 31/3835; G01R 31/392; G01R 31/396

(57) ABSTRACT

A method and a system for the prediction of the lifespan of a battery is provided. The method includes retrieving battery information including potential difference information indicative of a potential difference between a first terminal of a specific battery and a second terminal of the specific battery. The method further includes applying a machine learning (ML) model on the battery information. The ML model is trained to predict the lifespan of the specific battery. The method further includes determining lifespan information based on the application of the ML model on the battery information. The method further includes rendering the determined lifespan information.

### BACKGROUND

The disclosure relates to the prediction of the lifespan of a battery and more particularly, to the prediction of the lifespan of a battery using a machine learning (ML) model.

With recent advancements in the field of electronics and the growing demand for sustainable energy solutions, the demand for batteries has increased significantly. These batteries are now used in various applications, including consumer electronics like smartphones, laptops, cameras, wearables, electric vehicles (EVs), and the like. They are also used in medical devices like pacemakers and hearing aids, as well as in portable power tools like lawn mowers and electric screwdrivers. Specifically, batteries can be of different types depending upon the materials they are made of. For example, lithium-ion batteries which are known for their high energy density and long life, nickel-metal hydride (NiMH) batteries which are known for their reliability and environmental friendliness, lead-acid batteries which are known for their cost-effectiveness and high-power capacity, and emerging solid-state batteries. The advantages offered by these batteries are driving this growth towards the usage of battery-operated equipment.

However, batteries can lose their charge storage capacity due to degradation with usage and the passage of time. In many scenarios, batteries stop working without providing a warning or a prior message. This is problematic for any user who uses battery-operated equipment or a device that requires a battery.

### SUMMARY

According to an embodiment of the disclosure, a computer-implemented method for prediction of lifespan of a battery is described. The computer-implemented method includes retrieving, by a computer, battery information including potential difference information indicative of a potential difference between a first terminal of a specific battery and a second terminal of the specific battery. The battery information is obtained from one or more sources. The computer-implemented method further includes applying, by the computer, a machine learning (ML) model on the battery information. The ML model is trained to predict the lifespan of the specific battery. The lifespan of the specific battery corresponds to a time period until a charge storage capacity of the specific battery is above a threshold charge capacity. The computer-implemented method further includes determining, by the computer, lifespan information based on the application of the ML model on the battery information. The lifespan information is indicative of the lifespan of the specific battery. The computer-implemented method further includes rendering, by the computer, the determined lifespan information.

According to one or more embodiments of the disclosure, a system for prediction of lifespan of a battery is described. The system performs a method for prediction of the lifespan of the battery. The method includes retrieving battery information including potential difference information indicative of a potential difference between a first terminal of a specific battery and a second terminal of the specific battery. The battery information is retrieved from one or more sources. The method further includes applying a machine learning (ML) model on the battery information. The ML model is trained to predict the lifespan of the specific battery. The lifespan of the specific battery corresponds to a time period until a charge storage capacity of the specific battery is above a threshold charge capacity. The method further includes determining lifespan information based on the application of the ML model on the battery information. The lifespan information is indicative of the lifespan of the specific battery. The method further includes rendering the determined lifespan information.

According to one or more embodiments of the disclosure, a computer program product for prediction of lifespan of a battery is described. The computer program product includes a computer-readable storage medium having program instructions embodied therewith, the program instructions executable by a system to cause the system to retrieve battery information including potential difference information indicative of a potential difference between a first terminal of a specific battery and a second terminal of the specific battery The battery information is retrieved from one or more sources. The program instructions further include applying a machine learning (ML) model on the battery information. The ML model is trained to predict the lifespan of the specific battery. The lifespan of the specific battery corresponds to a time period until a charge storage capacity of the specific battery is above a threshold charge capacity. The program instructions further include determining lifespan information based on the application of the ML model on the battery information. The lifespan information is indicative of the lifespan of the specific battery. The program instructions further include rendering the determined lifespan information.

Additional technical features and benefits are realized through the techniques of the disclosure. Embodiments and aspects of the disclosure are described in detail herein and are considered a part of the claimed subject matter. For a better understanding, refer to the detailed description and to the drawings.

### BRIEF DESCRIPTION OF THE DRAWINGS

The following description will provide details of preferred embodiments with reference to the following figures wherein:

FIG. 1 is a diagram that illustrates a computing environment for prediction of lifespan of a battery, in accordance with an embodiment of the disclosure;

FIG. 2 is a diagram that illustrates an environment for prediction of lifespan of a battery using a machine learning (ML) model, in accordance with an embodiment of the disclosure;

FIG. 3A is a diagram that illustrates exemplary operations for generation of a set of clusters for training the ML model of FIG. 2, in accordance with an embodiment of the disclosure;

FIG. 3B is a diagram that illustrates exemplary operations for training the ML model of FIG. 2, in accordance with an embodiment of the disclosure;

FIG. 4 is a diagram that illustrates exemplary operations for prediction of lifespan of a battery using a machine learning (ML) model, in accordance with an embodiment of the disclosure;

FIG. 5 is a schematic diagram that illustrates exemplary steps for prediction of lifespan of a battery using a machine learning (ML) model, in accordance with an embodiment of the disclosure;

FIG. 6A is a diagram that depicts an exemplary first user interface for prediction of lifespan of a battery, in accordance with an embodiment of the disclosure;

FIG. 6B is a diagram that depicts an exemplary second user interface for prediction of lifespan of a battery, in accordance with an embodiment of the disclosure; and

FIG. 7 is a flowchart that illustrates an exemplary method for prediction of lifespan of a battery using a machine learning (ML) model, in accordance with an embodiment of the disclosure.

### DETAILED DESCRIPTION

Recent advancements in electronics and the increasing emphasis on sustainable energy solutions have significantly boosted the demand for batteries. These batteries have become an indispensable part of the day-to-day activities of people. For example, nowadays electric vehicles (EVs) have become a common mode of transportation, and they are mostly powered by lithium-ion batteries.

Moreover, the smartphones that people use nowadays are operated by lithium-ion batteries. As of now, most industries are using lead-acid batteries due to their cost-effectiveness and high-power capacity. These batteries have become indispensable in a wide range of applications, from consumer electronics like smartphones and laptops to electric vehicles (EVs) and renewable energy storage systems.

Despite their numerous advantages, batteries face challenges related to charge storage capacity degradation over time and with excessive use. In many scenarios, these batteries stop charging without providing a warning or a prior message. This is problematic for any user who uses battery-operated equipment or any device that requires a battery.

The increased reliance on batteries across various sectors underscores the need for more comprehensive and reliable methods to determine battery lifespan. As the demand for these batteries continues to rise, there is a need for the development of solutions or methods that can accurately predict battery performance and longevity. This is particularly crucial for applications where battery failure can have serious consequences, such as in medical devices and critical infrastructure.

One of the key challenges in improving battery lifespan determination is the diversity of battery types and their specific characteristics. While lithium-ion batteries have been extensively studied, other types of batteries require tailored approaches to accurately determine their lifespan. Therefore, there is a requirement for advanced diagnostic tools and techniques that can cater to the unique properties of each battery type.

In addition to addressing the diversity of battery types, the limitations of low-power IoT devices need to be considered in monitoring battery health. These devices often operate with minimal processing power and storage capacity, making it difficult to implement traditional battery monitoring methods. Innovative solutions are needed to enable effective battery lifespan assessment in these constrained environments, ensuring that IoT devices can continue to function reliably over extended periods.

Traditional methods for determining battery life expectancy have primarily focused on lithium-ion batteries, leaving a gap in addressing the needs of other battery types. Moreover, these conventional methods are not suitable for low-power IoT (Internet of Things) devices, which lack the required processing power and storage capacity to monitor battery lifespan effectively.

Therefore, the increasing demand for batteries across various applications highlights the need for improved methods to determine battery lifespan. Therefore, there is a need for an improved method of determination of battery lifespan to address the challenges of battery degradation, diversity of battery types, and limitations of low-power IoT devices.

According to an embodiment of the disclosure, a computer-implemented method for prediction of lifespan of a battery is described. The computer-implemented method includes retrieving, by a computer, battery information including potential difference information indicative of a potential difference between a first terminal of a specific battery and a second terminal of the specific battery. The battery information is obtained from one or more sources. The computer-implemented method further includes applying, by the computer, a machine learning (ML) model on the battery information. The ML model is trained to predict the lifespan of the specific battery. The lifespan of the specific battery corresponds to a time period until a charge storage capacity of the specific battery is above a threshold charge capacity. The computer-implemented method further includes determining, by the computer, lifespan information based on the application of the ML model on the battery information. The lifespan information is indicative of the lifespan of the specific battery. The computer-implemented method further includes rendering, by the computer, the determined lifespan information.

In other embodiments of the disclosure, the battery information associated with the specific battery further includes at least one of battery composition information, battery vendor information, battery usage environment information, or battery age information.

In other embodiments of the disclosure, the computer-implemented method further includes obtaining, by the computer, a first set of features associated with each battery of a set of batteries. The specific battery is excluded from the set of batteries. The computer-implemented method further includes applying, by the computer, a clustering technique on the first set of features associated with each battery of the set of batteries to generate a set of clusters associated with at least a composition of each battery of the set of batteries.

In other embodiments of the disclosure, the first set of features includes at least one of a first feature associated with the composition of each battery of the set of batteries, a second feature associated with a vendor of each battery of the set of batteries, a third feature associated with a voltage of each battery of the set of batteries, a fourth feature associated with a voltage per cell of each battery of the set of batteries, a fifth feature associated with a nominal charge capacity of each battery of the set of batteries, a sixth feature associated with an energy density of each battery of the set of batteries, a seventh feature associated with an operating temperature range of each battery of the set of batteries, or an eighth feature associated with dimensions of each battery of the set of batteries.

In other embodiments of the disclosure, the computer-implemented method further includes obtaining, by the computer, a second set of features associated with each battery of the set of batteries. The computer-implemented method further includes generating, by the computer, a training dataset based on the second set of features. The computer-implemented method further includes training, by the computer, the ML model based on the set of clusters and the training dataset.

In other embodiments of the disclosure, the second set of features further includes at least one of a first feature associated with the potential difference between the first terminal and the second terminal of each battery of the set of batteries, a second feature associated with an aging model of each battery of the set of batteries, a third feature associated with a resistance of each battery of the set of batteries, a fourth feature associated with a charge capacity of each battery of the set of batteries, a fifth feature associated with an operating temperature of each battery of the set of batteries, or a sixth feature associated with an actual lifespan of each battery of the set of batteries.

In other embodiments of the disclosure, the ML model corresponds to a multivariable polynomial regression model.

In other embodiments of the disclosure, the computer-implemented method further includes receiving, by the computer, feedback associated with the lifespan of the specific battery from a user device. The computer-implemented method further includes training, by the computer, the ML model based on the feedback.

According to one or more embodiments of the disclosure, a system for prediction of lifespan of a battery is described. The system performs a method for prediction of the lifespan of the battery. The method includes retrieving battery information including potential difference information indicative of a potential difference between a first terminal of a specific battery and a second terminal of the specific battery. The battery information is retrieved from one or more sources. The method further includes applying a machine learning (ML) model on the battery information. The ML model is trained to predict the lifespan of the specific battery. The lifespan of the specific battery corresponds to a time period until a charge storage capacity of the specific battery is above a threshold charge capacity. The method further includes determining lifespan information based on an application of the ML model on the battery information. The lifespan information is indicative of the lifespan of the specific battery. The method further includes rendering the determined lifespan information.

In other embodiments of the disclosure, the battery information associated with the specific battery further includes at least one of battery composition information, battery vendor information, battery usage environment information, or battery age information.

In other embodiments of the disclosure, the system further obtains a first set of features associated with each battery of a set of batteries. The specific battery is excluded from the set of batteries. The system further applies a clustering technique on the first set of features associated with each battery of the set of batteries to generate a set of clusters associated with at least a composition of each battery of the set of batteries.

In other embodiments of the disclosure, the first set of features includes at least one of a first feature associated with the composition of each battery of the set of batteries, a second feature associated with a vendor of each battery of the set of batteries, a third feature associated with a voltage of each battery of the set of batteries, a fourth feature associated with a voltage per cell of each battery of the set of batteries, a fifth feature associated with a nominal charge capacity of each battery of the set of batteries, a sixth feature associated with an energy density of each battery of the set of batteries, a seventh feature associated with an operating temperature range of each battery of the set of batteries, or an eighth feature associated with dimensions of each battery of the set of batteries.

In other embodiments of the disclosure, the system further obtains a second set of features associated with each battery of the set of batteries. The system further generates a training dataset based on the second set of features. The system further trains the ML model based on the set of clusters and the training dataset.

In other embodiments of the disclosure, the second set of features further includes at least one of a first feature associated with the potential difference between the first terminal and the second terminal of each battery of the set of batteries, a second feature associated with an aging model of each battery of the set of batteries, a third feature associated with a resistance of each battery of the set of batteries, a fourth feature associated with a charge capacity of each battery of the set of batteries, a fifth feature associated with an operating temperature of each battery of the set of batteries, or a sixth feature associated with an actual lifespan of each battery of the set of batteries.

In other embodiments of the disclosure, the ML model corresponds to a multivariable polynomial regression model.

In other embodiments of the disclosure, the system further receives feedback associated with the lifespan of the specific battery from a user device. The system further trains the ML model based on the feedback.

According to one or more embodiments of the disclosure, a computer program product for prediction of lifespan of a battery is described. The computer program product includes a computer-readable storage medium having program instructions embodied therewith, the program instructions executable by a system to cause the system to retrieve battery information including potential difference information indicative of a potential difference between a first terminal of a specific battery and a second terminal of the specific battery The battery information is retrieved from one or more sources. The program instructions further include applying a machine learning (ML) model on the battery information. The ML model is trained to predict the lifespan of the specific battery. The lifespan of the specific battery corresponds to a time period until a charge storage capacity of the specific battery is above a threshold charge capacity. The program instruction further includes determining lifespan information based on the application of the ML model on the battery information. The lifespan information is indicative of the lifespan of the specific battery. The method further includes rendering the determined lifespan information.

In other embodiments of the disclosure, the battery information associated with the specific battery further includes at least one of battery composition information, battery vendor information, battery usage environment information, or battery age information.

In other embodiments of the disclosure, the program instructions further include obtaining a first set of features associated with each battery of a set of batteries. The specific battery is excluded from the set of batteries. The program instruction further includes applying a clustering technique on the first set of features associated with each battery of the set of batteries to generate a set of clusters associated with at least a composition of each battery of the set of batteries.

In other embodiments of the disclosure, the program instructions further include obtaining a second set of features associated with each battery of the set of batteries. The program instruction further includes generating a training dataset based on the second set of features. The program instruction further includes training the ML model based on the set of clusters and the training dataset.

Various aspects of the disclosure are described by narrative text, flowcharts, block diagrams of computer systems and/or block diagrams of the machine logic included in computer program product (CPP) embodiments. With respect to any flowcharts, depending upon the technology involved, the operations can be performed in a different order than what is shown in a given flowchart. For example, again depending upon the technology involved, two operations shown in successive flowchart blocks is performed in reverse order, as a single integrated operation, concurrently, or in a manner at least partially overlapping in time.

A computer program product embodiment (“CPP embodiment” or “CPP”) is a term used in the disclosure to describe any set of one, or more, storage media (also called “mediums”) collectively included in a set of one, or more, storage devices that collectively include machine readable code corresponding to instructions and/or data for performing computer operations specified in a given CPP claim. A “storage device” is any tangible device that can retain and store instructions for use by a computer processor. Without limitation, the computer-readable storage medium is an electronic storage medium, a magnetic storage medium, an optical storage medium, an electromagnetic storage medium, a semiconductor storage medium, a mechanical storage medium, or any suitable combination of the foregoing. Some known types of storage devices that include these mediums include diskette, hard disk, random access memory (RAM), read-only memory (ROM), erasable programmable read-only memory (EPROM or Flash memory), static random access memory (SRAM), compact disc read-only memory (CD-ROM), digital versatile disk (DVD), memory stick, floppy disk, mechanically encoded device (such as punch cards or pits/lands formed in a major surface of a disc) or any suitable combination of the foregoing. A computer-readable storage medium, as that term is used in the disclosure, is not to be construed as storage in the form of transitory signals per se, such as radio waves or other freely propagating electromagnetic waves, electromagnetic waves propagating through a waveguide, light pulses passing through a fiber optic cable, electrical signals communicated through a wire, and/or other transmission media. As will be understood by those of skill in the art, data is typically moved at some occasional points in time during normal operations of a storage device, such as during access, de-fragmentation, or garbage collection, but this does not render the storage device as transitory because the data is not transitory while it is stored.

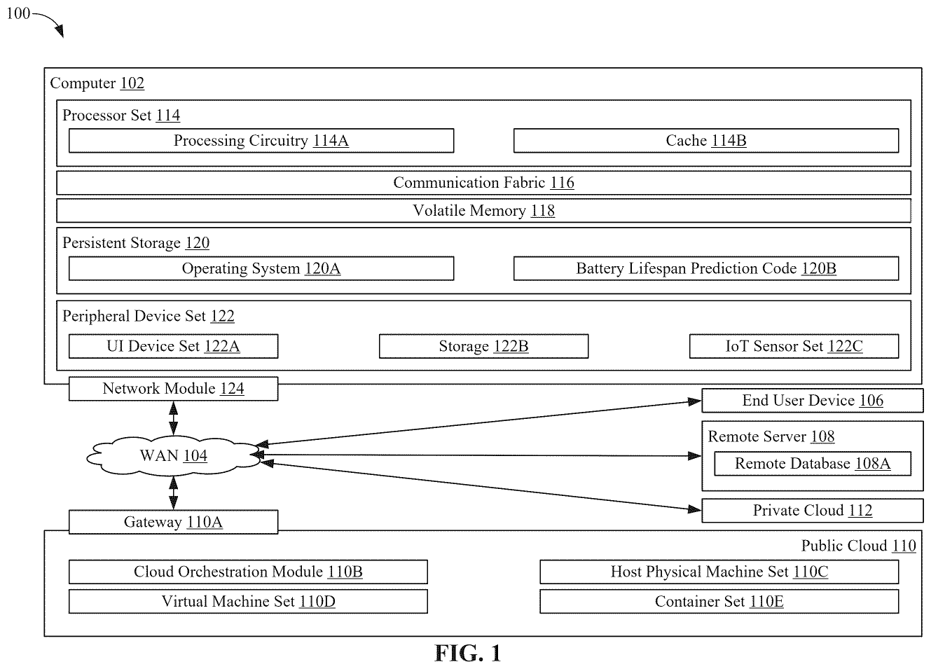

FIG. 1 is a diagram that illustrates a computing environment for prediction of lifespan of a battery, in accordance with an embodiment of the disclosure. With reference to FIG. 1, there is shown a computing environment 100 that contains an example of an environment for the execution of at least some of the computer code involved in performing the disclosed methods, such as a battery lifespan prediction code 120B. In addition to the battery lifespan prediction code 120B, computing environment 100 includes, for example, a computer 102, a wide area network (WAN) 104, an end user device (EUD) 106, a remote server 108, a public cloud 110, and a private cloud 112. In this embodiment of the disclosure, the computer 102 includes a processor set 114 (including a processing circuitry 114A and a cache 114B), a communication fabric 116, a volatile memory 118, a persistent storage 120 (including an operating system 120A and the battery lifespan prediction code 120B, as identified above), a peripheral device set 122 (including a user interface (UI) device set 122A, a storage 122B, and an Internet of Things (IoT) sensor set 122C), and a network module 124. The remote server 108 includes a remote database 108A. The public cloud 110 includes a gateway 110A, a cloud orchestration module 110B, a host physical machine set 110C, a virtual machine set 110D, and a container set 110E.

The computer 102 may take the form of a desktop computer, a laptop computer, a tablet computer, a smartphone, a smartwatch or other wearable computer, a mainframe computer, a quantum computer, or any other form of a computer or a mobile device now known or to be developed in the future that is capable of running a program, accessing a network or querying a database, such as a remote database 130. As is well understood in the art of computer technology, and depending upon the technology, the performance of a computer-implemented method may be distributed among multiple computers and/or between multiple locations. On the other hand, in this presentation of the computing environment 100, detailed discussion is focused on a single computer, specifically the computer 102, to keep the presentation as simple as possible. The computer 102 may be located in a cloud, even though it is not shown in a cloud in FIG. 1. On the other hand, computer 102 is not required to be in a cloud except to any extent as is affirmatively indicated.

The processor set 114 includes one, or more, computer processors of any type now known or to be developed in the future. The processing circuitry 114A may be distributed over multiple packages, for example, multiple, coordinated integrated circuit chips. The processing circuitry 114A may implement multiple processor threads and/or multiple processor cores. The cache 114B is a memory that is located in the processor chip package(s) and is typically used for data or code that should be available for rapid access by the threads or cores running on the processor set 114. Cache memories are typically organized into multiple levels depending upon relative proximity to the processing circuitry 114A. Alternatively, some, or all, of the cache 114B for the processor set 114 may be located “off-chip.” In some computing environments, the processor set 114 may be designed for working with qubits and performing quantum computing.

Computer readable program instructions are typically loaded onto the computer 102 to cause a series of operations to be performed by the processor set 114 of the computer 102 and thereby effect a computer-implemented method, such that the instructions thus executed will instantiate the methods specified in flowcharts and/or narrative descriptions of computer-implemented methods included in this document (collectively referred to as “the disclosed methods”). These computer-readable program instructions are stored in various types of computer-readable storage media, such as the cache 114B and the other storage media discussed below. The program instructions, and associated data, are accessed by the processor set 114 to control and direct the performance of the disclosed methods. In computing environment 100, at least some of the instructions for performing the disclosed methods may be stored in the dynamic modification of the battery lifespan prediction code 120B in persistent storage 120.

The communication fabric 116 is the signal conduction path that allows the various components of computer 102 to communicate with each other. Typically, this fabric is made of switches and electrically conductive paths, such as the switches and electrically conductive paths that make up buses, bridges, physical input/output ports, and the like. Other types of signal communication paths are used, such as fiber optic communication paths and/or wireless communication paths.

The volatile memory 118 is any type of volatile memory now known or to be developed in the future. Examples include dynamic type random access memory (RAM) or static type RAM. Typically, the volatile memory 118 is characterized by a random access, but this is not required unless affirmatively indicated. In the computer 102, the volatile memory 118 is located in a single package and is internal to computer 102, but alternatively or additionally, the volatile memory 118 may be distributed over multiple packages and/or located externally with respect to computer 102.

The persistent storage 120 is any form of non-volatile storage for computers that is now known or to be developed in the future. The non-volatility of this storage means that the stored data is maintained regardless of whether power is being supplied to computer 102 and/or directly to the persistent storage 120. The persistent storage 120 is a read-only memory (ROM), but typically at least a portion of the persistent storage 120 allows writing of data, deletion of data, and re-writing of data. Some familiar forms of the persistent storage 120 include magnetic disks and solid-state storage devices. The operating system 120A may take several forms, such as various known proprietary operating systems or open-source Portable Operating System Interface-type operating systems that employ a kernel. The code included in the battery lifespan prediction code 120B typically includes at least some of the computer code involved in performing the disclosed methods.

The peripheral device set 122 includes the set of peripheral devices of computer 102. Data communication connections between the peripheral devices and the other components of computer 102 may be implemented in various ways, such as Bluetooth connections, Near-Field Communication (NFC) connections, connections made by cables (such as universal serial bus (USB) type cables), insertion-type connections (for example, secure digital (SD) card), connections made through local area communication networks and even connections made through wide area networks such as the internet. In various embodiments of the disclosure, the UI device set 122A includes components such as a display screen, speaker, microphone, wearable devices (such as goggles and smartwatches), keyboard, mouse, printer, touchpad, game controllers, and haptic devices. The storage 122B is external storage, such as an external hard drive, or insertable storage, such as an SD card. The storage 122B is persistent and/or volatile. In some embodiments of the disclosure, storage 122B may take the form of a quantum computing storage device for storing data in the form of qubits. In embodiments of the disclosure where computer 102 is required to have a large amount of storage (for example, where computer 102 locally stores and manages a large database) then this storage may be provided by peripheral storage devices designed for storing very large amounts of data, such as a storage area network (SAN) that is shared by multiple, geographically distributed computers. The IoT sensor set 122C is made up of sensors that can be used in Internet of Things applications. For example, one sensor may be a thermometer, and another sensor may be a motion detector.

The network module 124 is the collection of computer software, hardware, and firmware that allows computer 102 to communicate with other computers through WAN 104. The network module 124 may include hardware, such as modems or Wi-Fi signal transceivers, software for packetizing and/or de-packetizing data for communication network transmission, and/or web browser software for communicating data over the internet. In some embodiments of the disclosure, network control functions, and network forwarding functions of the network module 124 are performed on the same physical hardware device. In other embodiments of the disclosure (for example, embodiments that utilize software-defined networking (SDN)), the control functions and the forwarding functions of the network module 124 are performed on physically separate devices, such that the control functions manage several different network hardware devices. Computer-readable program instructions for performing the disclosed methods can typically be downloaded to computer 102 from an external computer or external storage device through a network adapter card or network interface included in the network module 124.

The WAN 104 is any wide area network (for example, the internet) capable of communicating computer data over non-local distances by any technology for communicating computer data, now known or to be developed in the future. In some embodiments of the disclosure, the WAN 104 may be replaced and/or supplemented by local area networks (LANs) designed to communicate data between devices located in a local area, such as a Wi-Fi network. The WAN 104 and/or LANs typically include computer hardware such as copper transmission cables, optical transmission fibers, wireless transmission, routers, firewalls, switches, gateway computers, and edge servers.

The EUD 106 is any computer system that is used and controlled by an end user (for example, a customer of an enterprise that operates computer 102) and may take any of the forms discussed above in connection with computer 102. The EUD 106 typically receives helpful and useful data from the operations of computer 102. For example, in a hypothetical case where computer 102 is designed to provide a recommendation to an end user, this recommendation would typically be communicated from the network module 124 of computer 102 through WAN 104 to EUD 106. In this way, the EUD 106 can display, or otherwise present recommendations to an end user. In some embodiments of the disclosure, EUD 106 may be a client device, such as a thin client, heavy client, mainframe computer, desktop computer, and so on.

The remote server 108 is any computer system that serves at least some data and/or functionality to the computer 102. The remote server 108 may be controlled and used by the same entity that operates the computer 102. The remote server 108 represents the machine(s) that collect and store helpful and useful data for use by other computers, such as the computer 102. For example, in a hypothetical case where the computer 102 is designed and programmed to provide a recommendation based on historical data, then this historical data may be provided to the computer 102 from the remote database 130 of the remote server 108.

The public cloud 110 is any computer system available for use by multiple entities that provides on-demand availability of computer system resources and/or other computer capabilities, especially data storage (cloud storage) and computing power, without direct active management by the user. Cloud computing typically leverages the sharing of resources to achieve coherence and economies of scale. The direct and active management of the computing resources of the public cloud 110 is performed by the computer hardware and/or software of the cloud orchestration module 110B. The computing resources provided by the public cloud 110 are typically implemented by virtual computing environments that run on various computers making up the computers of the host physical machine set 110C, which is the universe of physical computers in and/or available to the public cloud 110. The virtual computing environments (VCEs) typically take the form of virtual machines from the virtual machine set 110D and/or containers from the container set 110E. It is understood that these VCEs may be stored as images and may be transferred among and between the various physical machine hosts, either as images or after the instantiation of the VCE. The cloud orchestration module 110B manages the transfer and storage of images, deploys new instantiations of VCEs, and manages active instantiations of VCE deployments. The gateway 110A is the collection of computer software, hardware, and firmware that allows public cloud 110 to communicate through WAN 104.

Some further explanation of virtualized computing environments (VCEs) will now be provided. VCEs can be stored as “images”. A new active instance of the VCE can be instantiated from the image. Two familiar types of VCEs are virtual machines and containers. A container is a VCE that uses operating-system-level virtualization. This refers to an operating system feature in which the kernel allows the existence of multiple isolated user-space instances, called containers. These isolated user-space instances typically behave as real computers from the point of view of programs running in them. A computer program running on an ordinary operating system can utilize all resources of that computer, such as connected devices, files and folders, network shares, CPU power, and quantifiable hardware capabilities. However, programs running inside a container can only use the contents of the container and devices assigned to the container, a feature which is known as containerization.

The private cloud 112 is similar to public cloud 110, except that the computing resources are only available for use by a single enterprise. While the private cloud 112 is depicted as being in communication with the WAN 104, in other embodiments of the disclosure, a private cloud may be disconnected from the internet entirely and only accessible through a local/private network. A hybrid cloud is a composition of multiple clouds of different types (for example, private, community, or public cloud types), often respectively implemented by different vendors. Each of the multiple clouds remains a separate and discrete entity, but the larger hybrid cloud architecture is bound together by standardized or proprietary technology that enables orchestration, management, and/or data/application portability between the multiple constituent clouds. In this embodiment of the disclosure, the public cloud 110 and the private cloud 112 are both part of a larger hybrid cloud.

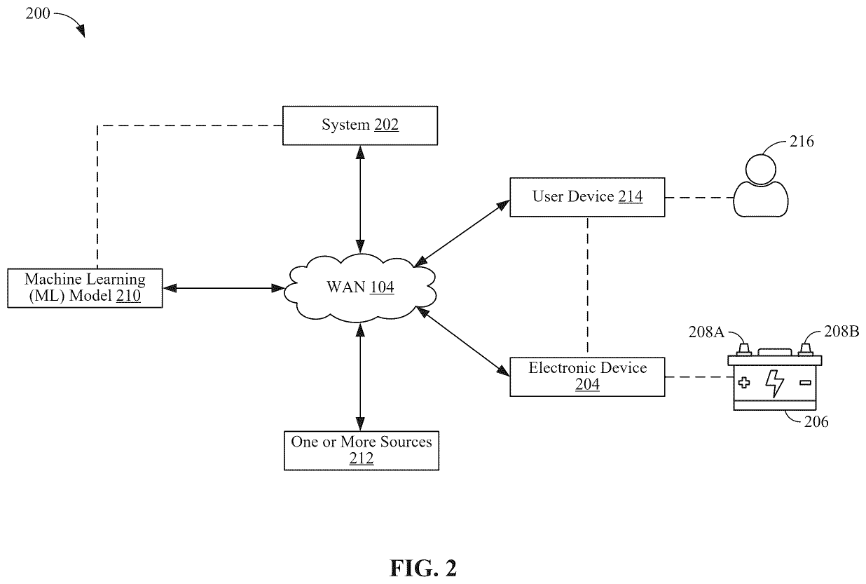

FIG. 2 is a diagram that illustrates an environment for prediction of lifespan of a battery, in accordance with an embodiment of the disclosure. FIG. 2 is explained in conjunction with elements from FIG. 1. With reference to FIG. 2, there is shown a diagram of a network environment 200. The network environment 200 includes a system 202, an electronic device 204, and a battery 206 (also referred to as a specific battery) associated with the electronic device 204. There is further shown a first terminal 208A of the battery 206 and a second terminal 208B of the battery 206. The network environment 200 further includes a machine learning (ML) model 210, one or more sources 212, a user device 214, and a user 216 associated with the user device 214. The network environment 200 further includes the WAN 104 of FIG. 1. In an embodiment of the disclosure, each of the electronic device 204 and the user device 214 is an exemplary embodiment of the EUD 106. Similarly, the system 202 is an exemplary embodiment of the computer 102 in FIG. 1.

The system 202 includes suitable logic, circuitry, and/or interfaces for the prediction of the lifespan of the battery 206. The system 202 retrieves battery information including potential difference information indicative of a potential difference between the first terminal 208A of the battery 206 (or the specific battery) and the second terminal 208B of the battery 206. The battery information is retrieved from one or more sources 212. The system 202 further applies the ML model 210 on the battery information. The ML model 210 is trained to predict the lifespan of the battery 206. The system 202 further determines lifespan information based on the application of the ML model 210 on the battery information. The system 202 further renders the determined lifespan information.

Examples of the system 202 include, but are not limited to, a server, a computing device, a virtual computing device, a mainframe machine, a computer workstation, a smartphone, a cellular phone, a mobile phone, a gaming device, or a consumer electronic (CE) device. In an example embodiment of the disclosure, the system 202 may be embodied as a cloud-based service, a cloud-based application, a cloud-based platform, a remote server-based service, a remote server-based application, a remote server-based platform, or a virtual computing system.

The electronic device 204 includes suitable logic, circuitry, and/or interfaces to execute one or more tasks within the network environment 200. The electronic device 204 performs various operations such as receiving data, processing the data, and transmitting the data. In an embodiment of the disclosure, the electronic device 204 includes the battery 206 for supplying power for execution of the one or more tasks. Examples of the electronic device 204 include, but are not limited to, an Internet of Things (IoT) device, a smartphone, a cellular phone, a mobile phone, a consumer electronic (CE) device, a computing device, a mainframe machine, a server, or a computer workstation.

The battery 206 (the specific battery) corresponds to an electrochemical device that stores and releases electrical energy through reversible chemical reactions. In an embodiment of the disclosure, the battery 206 includes the first terminal 208A (or a positively charged cathode) and the second terminal 208B (or a negatively charged anode). The first terminal 208A and the second terminal 208B are made from materials that can undergo reduction and oxidation reactions. The battery 206 further includes an electrolyte. The electrolyte is a medium that allows the flow of ions between the first terminal 208A and the second terminal 208B. The electrolyte can be in a liquid, a gel, or a solid form. During discharge, the second terminal 208B undergoes oxidation, releasing electrons that flow through a circuit to the first terminal 208A, where reduction occurs. During charging of the battery 206, the first terminal 208A undergoes oxidation and the electrons flow towards the second terminal, where the reduction occurs. The electrolyte facilitates the movement of ions to balance the charge.

In an embodiment of the disclosure, the battery 206 is embedded in the electronic device 204 and serves as a power supply unit for the electronic device 204. The battery 206 supplies power to the electronic device 204 for performing various operations. Based on different chemical compositions of the electrolyte of the battery 206, examples of the battery 206 may correspond to one of, but are not limited to, a lithium-ion battery, a nickel-metal hydride (NiMH) battery, a non-lithium battery, a lead-acid battery, an Absorbent Glass Mat (AGM) battery, or an Enhanced Flooded Battery (EFB).

In an alternate embodiment of the disclosure, the battery 206 may be associated with the electronic device 204 and serves as the power supply unit for the electronic device 204. In such an embodiment of the disclosure, the battery 206 may be a separate entity from the electronic device 204.

The ML model 210 corresponds to a neural network-based regression model. The neural network is a computational network or a system of artificial neurons, arranged in a plurality of layers, as nodes. The plurality of layers of the neural network may include an input layer, one or more hidden layers, and an output layer. Each layer of the plurality of layers may include one or more nodes (or artificial neurons). Outputs of all nodes in the input layer may be coupled to at least one node of the hidden layer(s). Similarly, inputs of each hidden layer are coupled to outputs of at least one node in other layers of the neural network. Outputs of each hidden layer may be coupled to inputs of at least one node in other layers of the neural network. Node(s) in the final layer may receive inputs from at least one hidden layer to output a result.

The number of layers and the number of nodes in each layer may be determined from hyper-parameters of the neural network. Such hyper-parameters may be set before or while training the neural network on a training dataset. Each node of the neural network corresponds to a mathematical function (e.g., a sigmoid function or a rectified linear unit) with a set of parameters, tunable during training of the neural network. The set of parameters includes, for example, a weight parameter, a regularization parameter, and the like. Each node uses the mathematical function to compute an output based on one or more inputs from nodes in other layer(s) (e.g., previous layer(s)) of the neural network. All or some of the nodes of the neural network correspond to the same or a different mathematical function.

The neural network includes electronic data, such as, for example, a software program, code of the software program, libraries, applications, scripts, or other logic or instructions for execution by a processing device, such as circuitry. The neural network may be implemented using hardware including a processor, a microprocessor (e.g., to perform or control the performance of one or more operations), a field-programmable gate array (FPGA), or an application-specific integrated circuit (ASIC). Alternatively, in some embodiments, the neural network may be implemented using a combination of hardware and software. Accordingly, in some embodiments, the ML model 210 is a separate entity in the system 202, without deviation from the scope of the disclosure.

In an embodiment of the disclosure, the system 202 trains the ML model 210 to predict the lifespan of the battery 206 based on the battery information that includes the potential difference between the first terminal 208A and the second terminal 208B of the battery 206. In another embodiment of the disclosure, the system 202 stores the ML model 210. In an alternate embodiment of the disclosure, the ML model 210 is embodied as a cloud-based service, a cloud-based application, or a cloud-based platform. Examples of the ML model 210 include, but are not limited to, an artificial neural network (ANN), a deep neural network (DNN), a convolutional neural network (CNN), a fully connected neural network, and/or a combination of such networks.

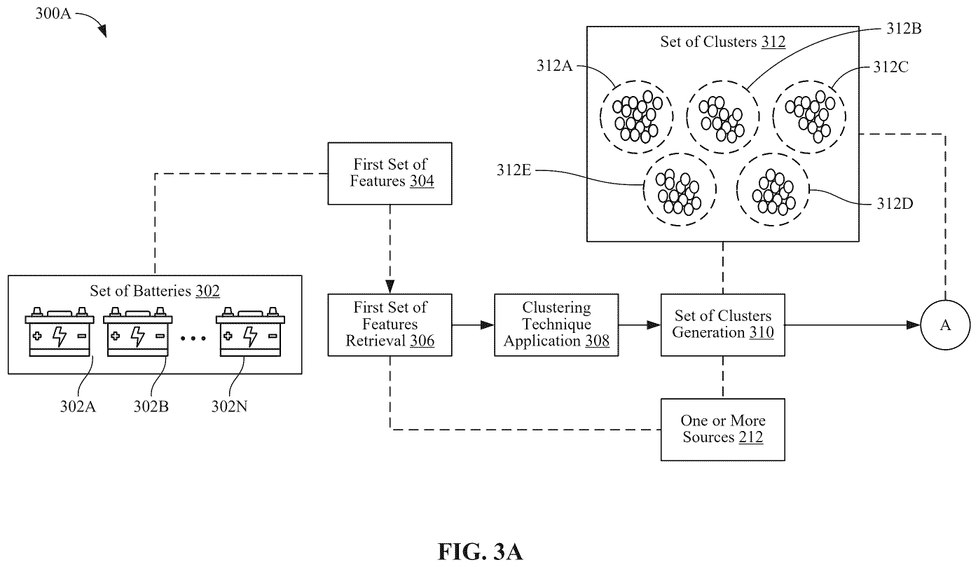

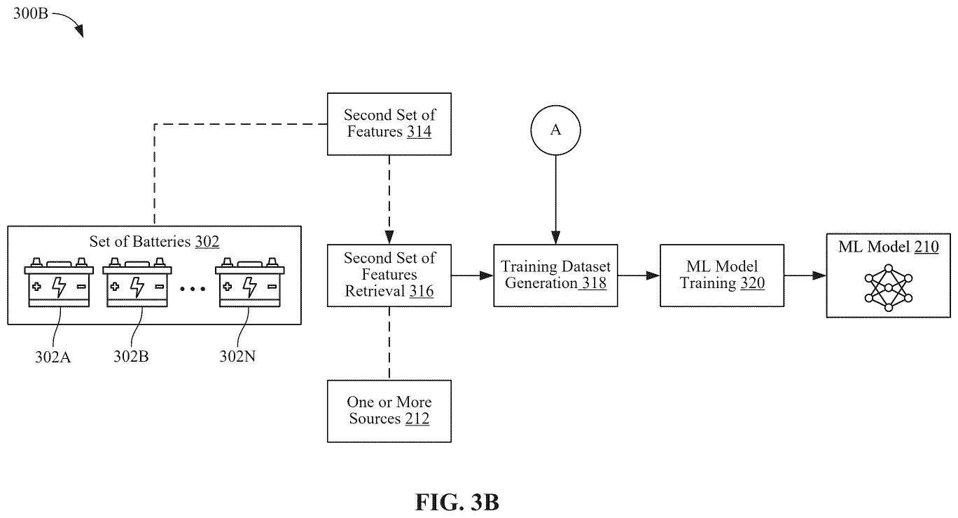

Each of the one or more sources 212 corresponds to a database, which refers to an organized collection of data that may be stored and accessed electronically from a computer system (such as the system 202). In an embodiment of the disclosure, each of the one or more sources 212 may be associated with the system 202 and stores the battery information associated with the specific battery. The one or more sources 212 further stores a first set of features associated with a set of batteries, a second set of features associated with the set of batteries, and a training dataset that may be used to train the ML model 210. Details about the first set of features, the second set of features, and the training dataset are provided in, for example, FIG. 3A and FIG. 3B. Each of the one or more sources 212 may be designed to manage, store, retrieve, and update data efficiently. The structure of the database associated with each of the one or more sources typically involves tables, records, and fields that can be managed through various database management systems (DBMS). Examples of each of the one or more sources 212 include, but are not limited to, a relational database, a Non-Structured Query Language (SQL) database, a hierarchical database, a network database, a transactional database, a data warehouse, and a distributed database.

The user device 214 includes suitable logic, circuitry, interfaces, and/or code for receiving a user input including the battery information from the user 216, and transmitting the received battery information to the system 202. In an embodiment of the disclosure, the user device 214 further renders the message including the lifespan of the battery 206 received from the system 202 on a display screen associated with the user device 214. Example of the user device 214 includes one of, but is not limited to, a computing device, a mainframe machine, a server, a computer workstation, a smartphone, a cellular phone, a mobile phone, a gaming device, a consumer electronic (CE) device or the like.

In operation, the system 202 retrieves the battery information including the potential difference information indicating the potential difference between the first terminal 208A of the battery 206 (the specific battery) and the second terminal 208B of the battery 206 (the specific battery). The battery information is associated with the battery 206 (the specific battery). The battery information is retrieved from the one or more sources 212. In an embodiment of the disclosure, the system 202 receives the battery information associated with the battery 206 from the user device 214 associated with the electronic device 204.

In an alternate embodiment of the disclosure, the system 202 retrieves the potential difference between the first terminal 208A of the battery 206 and the second terminal 208B of the battery 206 from a voltmeter associated with the electronic device 204. In yet another alternate embodiment of the disclosure, the system 202 retrieves the battery information (the potential difference) from the first terminal 208A and the second terminal 208B of the battery 206.

Thereafter, the system 202 applies ML model 210 on the battery information. The ML model 210 is trained to predict the lifespan of the battery 206 (the specific battery). The lifespan of the battery 206 (the specific battery) corresponds to the time period until the charge storage capacity of the battery 206 (the specific battery) is above a threshold charge capacity. In an example embodiment of the disclosure, the threshold charge capacity of the battery 206 is 80% of the charge storage capacity when the battery 206 is manufactured.

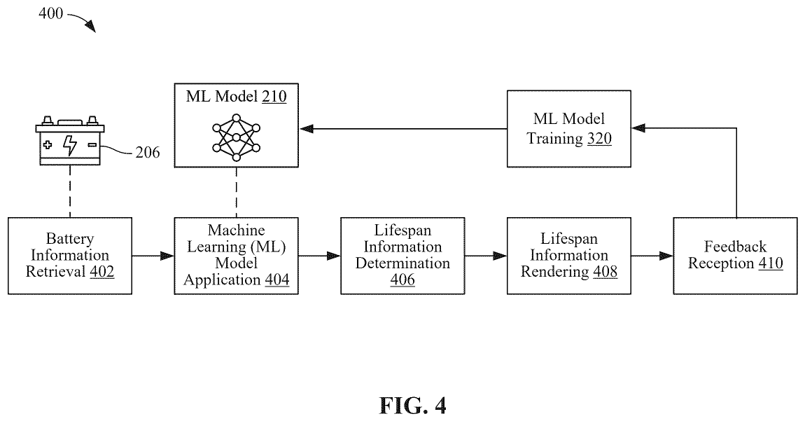

In an embodiment of the disclosure, the system 202 applies a clustering algorithm on the first set of features (obtained from the one or more sources 212) to generate a set of clusters associated with the set of batteries. The system 202 further trains the ML model 210 on the set of clusters and the training dataset for the prediction of lifespan of the battery 206 (the specific battery). Details about the generation of clusters and the training of the ML model 210 are provided in FIG. 3A, FIG. 3B, and FIG. 4.

In an embodiment of the disclosure, the ML model 210 takes a first timestamp (when the system 202 is used for the determination of lifespan information) as a reference and predicts a second timestamp (when the charge storage capacity of the battery 206 is just lesser than 80% of the charge storage capacity of the battery 206 at the first timestamp) as an output based on the battery information (the potential difference between the first terminal 208A of the battery 206 and the second terminal 208B of the battery 206). In an example embodiment of the disclosure, the ML model predicts that the lifespan of the battery is until, for example, “1 Apr. 2024” (the second timestamp) when the current date is “1 Jan. 2024” (the first timestamp).

Further, the system 202 determines the lifespan information based on the application of the ML model 210 on the battery information. The lifespan information is indicative of the lifespan of the battery 206 (the specific battery). The system 202 then determines the lifespan information associated with the specific battery based on the output generated by the application of the ML model 210 on the battery information. The lifespan information includes, for example, the lifespan of the specific battery. The lifespan information may optionally include a recommendation for the replacement of the specific battery if the charge capacity of the specific battery is less than the threshold charge capacity.

In an example embodiment of the disclosure, the system 202 determines the lifespan information based on calculating the time-period between the first timestamp (when the system 202 is used to determine the lifespan information) and the second timestamp (predicted by the ML model 210). The system 202 determines the lifespan information that the lifespan of the specific battery is, for example, 3 months from the current date (the date on which the system 202 determines the lifespan information) and the recommendation to replace the specific battery before 3 months.

To this end, the system 202 renders the determined lifespan information. In an embodiment of the disclosure, the system 202 renders the determined lifespan information including the lifespan of the specific battery which is predicted by the ML model 210 and the recommendation. In an embodiment of the disclosure, the system 202 renders the determined lifespan information on the display of the user device 214. In an alternate embodiment of the disclosure, the system 202 renders the lifespan information on the display of the electronic device 204.

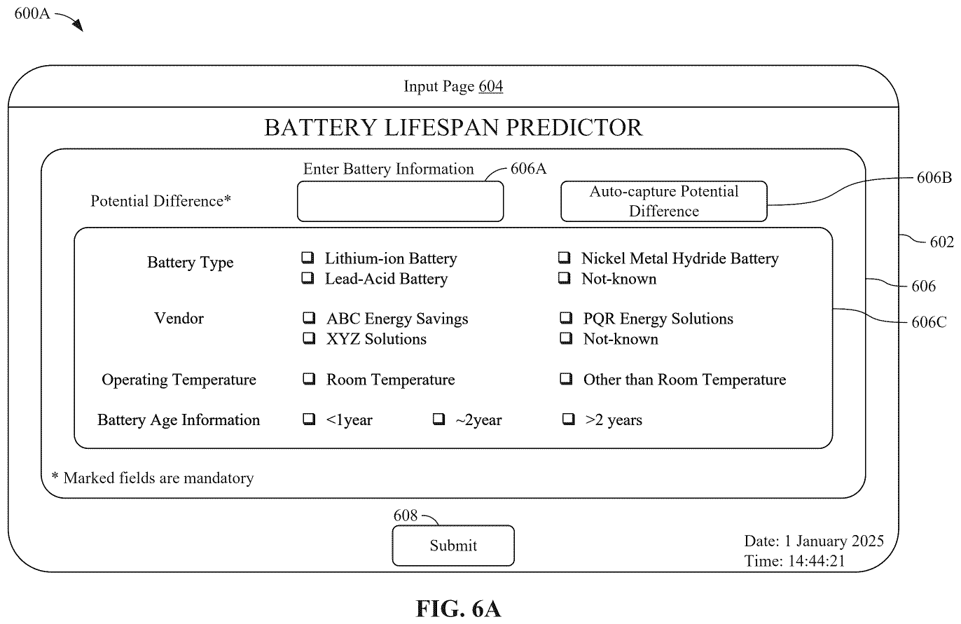

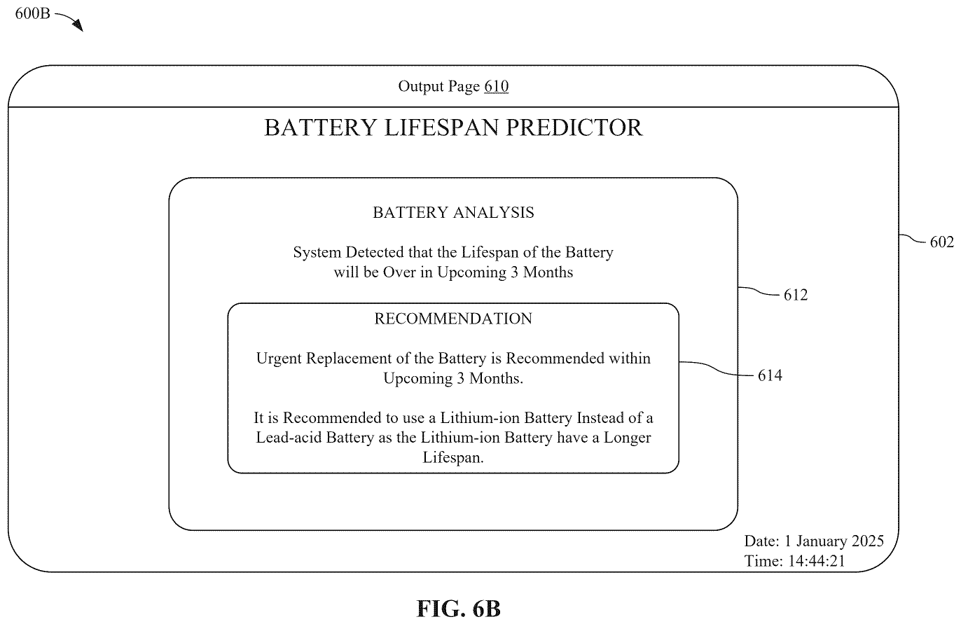

In an example embodiment of the disclosure, the system 202 renders the lifespan information including the information that the lifespan of the battery 206 will end after three months from the current date (the date on which the system 202 predicts the lifespan of the battery 206) and the recommendation to replace the battery 206 within three months. Details about the lifespan information rendering operation are provided in, for example, FIG. 4, FIG. 6A and FIG. 6B.

FIG. 3A is a block diagram 300A that illustrates exemplary operations for generation of a set of clusters for training the ML model of FIG. 2, in accordance with an embodiment of the disclosure. FIG. 3A is explained in conjunction with elements from FIG. 1 and FIG. 2. With reference to FIG. 3A, there is further shown a set of batteries 302 and a first set of features 304 associated with the set of batteries 302. The set of batteries 302 may include a first battery 302A, a second battery 302B, up to Nth battery 302N. With reference to FIG. 3A, there is shown the block diagram 300A that illustrates exemplary operations from 306 to 310, as described herein. The exemplary operations illustrated in the block diagram 300A start at 306 and are performed by any computing system, apparatus, or device, such as by the computer 102 of FIG. 1 or by the system 202 of FIG. 2. Each battery of the set of batteries 302 is an example embodiment of the battery 206 of FIG. 2. With reference to FIG. 3A, there is further shown a set of clusters 312 that includes, but is not limited to, a first cluster 312A, a second cluster 312B, a third cluster 312C, a fourth cluster 312D, and a fifth cluster 312E. Although illustrated with discrete blocks, the exemplary operations associated with one or more blocks of the block diagram 300A can be divided into additional blocks, combined into fewer blocks, or eliminated, depending on the implementation.

In an embodiment of the disclosure, the first set of features 304 includes at least one of a first feature associated with the composition of each battery of the set of batteries 302, a second feature associated with a vendor of each battery of the set of batteries 302, a third feature associated with a voltage of each battery of the set of batteries 302, a fourth feature associated with a voltage per cell of each battery of the set of batteries 302, a fifth feature associated with a nominal charge capacity of each battery of the set of batteries 302, a sixth feature associated with an energy density of each battery of the set of batteries 302, a seventh feature associated with an operating temperature range of each battery of the set of batteries 302, or an eighth feature associated with dimensions of each battery of the set of batteries 302.

The composition of each battery of the set of batteries 302 corresponds to the chemical composition of the electrolyte of each battery of the set of batteries 302. In an example embodiment of the disclosure, each battery of the set of batteries 302 is one of a lithium-ion battery, a nickel-metal hydride (NiMH) battery, a non-lithium battery, a lead-acid battery, an Absorbent Glass Mat (AGM) battery, an Enhanced Flooded Battery (EFB), or the like based on the composition of a corresponding battery of the set of batteries 302. The vendor of each battery of the set of batteries 302 corresponds to the manufacturer of the corresponding battery of the set of batteries 302. In an example embodiment of the disclosure, the vendor is one of, for example, but not limited to ABC Energy Savings, XYZ Solutions, or PQR Energy Solutions.

The voltage of each battery of the set of batteries 302 refers to a measure of the potential difference between the first terminal and the second terminal of each battery of the set of batteries 302 at a timestamp when the corresponding battery of the set of batteries 302 is manufactured. In an example embodiment of the disclosure, the voltage is one of, but not limited to 12V, 24V, 36V, or 48V. The voltage per cell of each battery of the set of batteries 302 refers to the potential difference generated by a corresponding cell within each battery of the set of batteries 302 at the timestamp when the corresponding battery is manufactured. In an example embodiment of the disclosure, the voltage per cell is one of, but not limited to, 1V, 1.5V, or 2V. The nominal (reference) charge capacity of each battery of the set of batteries 302 refers to the amount of electric charge stored in the corresponding battery of the set of batteries 302 when the battery is manufactured. In an example embodiment of the disclosure, the nominal charge capacity is one of, but not limited to, 4000 milli ampere hour (mAh), 5000 mAh, or 5500 mAh.

The energy density of each battery of the set of batteries 302 refers to the energy storing capacity of the corresponding battery relative to the weight of the corresponding battery of the set of batteries 302. In an example embodiment of the disclosure, the energy density is one of, but not limited to, 30 Watt-hours per kilogram (Wh/kg), 60 Wh/kg, or 90 Wh/kg. The operating temperature of each battery of the set of batteries 302 refers to the temperature of each battery when the corresponding battery is operating. The operating temperature is one of, but not limited to, 35 degrees Celsius, 40 degrees Celsius, or 45 degrees Celsius. The dimensions of each battery of the set of batteries 302 include the length of the corresponding battery, the width of the corresponding battery, and the height of the corresponding battery. In an example embodiment of the disclosure, the length is 80 mm, the width is 40 mm, and the height is 5 mm.

At 306, a first set of features retrieval operation is performed. In an embodiment of the disclosure, the system 202 obtains the first set of features 304 associated with each battery of the set of batteries 302. The specific battery is not included in the set of batteries 302. The system 202 obtains the first set of features 304 associated with each battery of the set of batteries 302 from the one or more sources 212. The first set of features 304 is associated with the battery information of each battery of the set of batteries 302. In an alternate embodiment of the disclosure, the system 202 obtains the first set of features associated with each battery of the set of batteries 302 from a set of user devices, which then is stored in the database associated with the one or more sources 212. Each user device of the set of user devices is an example embodiment of the user device 214 of FIG. 2.

At 308, a clustering technique application operation is performed. In an embodiment of the disclosure, the system 202 applies a clustering technique on the first set of features 304 to generate the set of clusters 312 associated with at least the composition of each battery of the set of batteries 302. The system 202 applies the clustering technique on each of the first feature, the second feature, the third feature, the fourth feature, the fifth feature, the sixth feature, the seventh feature, and the eight feature to generate the set of clusters 312 of the set of batteries 302. Each cluster of the set of clusters 312 includes one or more batteries from the set of batteries 302, which are alike in terms of one of the composition, the vendor, the voltage, the voltage per cell, the nominal charge capacity, the energy density, the operating temperature, or the dimensions.

In an embodiment of the disclosure, the system 202 applies a machine learning (ML) based clustering technique on the first set of features. The system 202 applies K nearest neighbours clustering technique on the first set of features. The K nearest neighbours is an ML-based clustering technique, which is used to form one or more clusters of the training dataset (stored in the database associated with the one or more sources 212) based on the Euclidean distance between one or more features of data points in the training dataset.

In an embodiment of the disclosure, the system 202 applies the K nearest neighbors' technique and determines a set of data points in the training dataset as a set of centroids. Then, the system 202 calculates the Euclidean distance between each data point in the training dataset from each centroid of the set of centroids. Further, the system 202 assigns each data point in the training dataset to the nearest centroid (which is closest to the corresponding data point in terms of the Euclidean distance) of the set of centroids to form the set of clusters 312 based on the calculated Euclidean distance. Further, the system 202 updates each centroid of the set of centroids based on the calculation of the mean of all data points in each cluster of the set of clusters. The system 202 updates each centroid of the set of centroids if the mean of all data points in each cluster of the set of clusters is different than the corresponding centroid of the corresponding cluster. This process is repeated until there are no further updates in each of the centroids.

In an alternate embodiment of the disclosure, the system 202 applies the hierarchical clustering technique on the first set of features 304 to generate the set of clusters 312. The system 202 applies the hierarchical clustering technique to initially generate one cluster including all the data points of the training dataset. Then, the system 202 splits the one cluster into the set of clusters 312 until a stopping criterion is met (for example, a desired number of clusters are generated). In an embodiment of the disclosure, the system 202 applies other machine learning-based algorithms for generating the set of clusters 312, for example, the mean-score clustering technique, but the details are not provided for the sake of brevity.

In an embodiment of the disclosure, the system 202 applies the K means clustering technique on the first set of features 304 to generate the set of clusters 312. As an example embodiment of the disclosure, the system 202 pre-processes the first set of features 304 to convert the alphanumeric data corresponding to the composition of each battery of the set of batteries 302 and the vendor information of each battery of the set of batteries 302 to numeric data based on the application of an encoding technique. The encoding technique may be, for example, label encoding.

Further, the system 202 includes 5 batteries (data points) in the set of centroids (k=5). Thereafter, the system 202 calculates the Euclidean distance between the first set of features 304 of each battery and the first set of features of each centroid of the set of centroids. The system 202 further assigns each battery to its nearest centroid (which is closest to the corresponding battery of the set of batteries 302 in terms of Euclidean distance) to obtain 5 clusters based on the Euclidean distance. The system 202 further calculates a mean of the first set of features 304 of all the one or more batteries in each cluster of the set of clusters. The system 202 further updates each centroid of the set of centroids based on the mean of the corresponding cluster. The system 202 then repeats the process until there are no further updates in each centroid of the set of centroids.

At 310, a set of clusters generation operation is performed. In an embodiment of the disclosure, the system 202 generates the set of clusters 312 based on the application of the clustering technique. The set of clusters is associated with at least the composition of each battery of the set of batteries. The set of clusters 312 includes at least the first cluster 312A, the second cluster 312B, the third cluster 312C, the fourth cluster 312D, and the fifth cluster 312E associated with the set of batteries 302.

In an embodiment of the disclosure, the system 202 generates the set of clusters based on the application of the clustering technique on the composition of each battery of the set of batteries 302. In an embodiment of the disclosure, the first cluster 312A of the set of clusters 312 includes lithium-ion batteries, the second cluster 312B of the set of clusters 312 includes lead-acid batteries, the third cluster 312C of the set of clusters 312 includes nickel-metal hydride (NiMH) batteries, the fourth cluster 312D of the set of clusters 312 includes Absorbent Glass Mat (AGM) batteries, the fifth cluster 312E of the set of cluster 312 includes Enhanced Flooded Batteries (EFB).

In an embodiment of the disclosure, the system 202 applies the K means clustering technique on the composition of each battery of the set of batteries 302 to group batteries that are alike in terms of the composition. The system 202 then generates the first cluster 312A of lithium-ion batteries, the second cluster 312B of lead-acid batteries, the third cluster 312C of metal hydride (NiMH) batteries, the fourth cluster 312D of Absorbent Glass Mat (AGM) batteries, and the fifth cluster 312E of Enhanced Flooded Batteries (EFB).

In an alternate embodiment of the disclosure, the system 202 generates the set of clusters 312 based on the application of the clustering technique on the composition of each battery of the set of batteries 302 and the operating temperature of each battery of the set of batteries 302. In an alternate embodiment of the disclosure, the system 202 generates the set of clusters 312 based on the composition of each battery of the set of batteries 302 and the vendor of each battery of the set of batteries 302. The first cluster 312A includes the one or more batteries manufactured by, for example, ABC Energy Savings. The second cluster 312B includes the one or more batteries manufactured by, for example, XYZ Solutions.

In yet another alternative embodiment of the disclosure, the system 202 generates the set of clusters based on the voltage of each battery of the set of batteries. The first cluster 312A includes 12V batteries, the second cluster 312B includes 24V batteries, the third cluster 312C includes 36V batteries and the fourth cluster 312D includes 48V batteries.

In an embodiment of the disclosure, the system 202 stores the set of clusters in the one or more sources 212. The system 202 stores the set of clusters in the one or more sources 212 for training the ML model 210. The system 202 further obtains the set of clusters from the one or more sources 212 for training the ML model 210 to predict the lifespan of the battery 206. Details about the training of the ML model 210 are provided, for example, in FIG. 3B.

FIG. 3B is a block diagram 300B that illustrates exemplary operations for training a Machine Learning (ML) model to predict the lifespan of a battery, in accordance with an embodiment of the disclosure. FIG. 3B is explained in conjunction with elements from FIG. 1, FIG. 2, and FIG. 3A. With reference to FIG. 3B, there is shown the block diagram 300B that illustrates exemplary operations from 316 to 320, as described herein. The exemplary operations illustrated in the block diagram 300B start at 316 and are performed by any computing system, apparatus, or device, such as by the computer 102 of FIG. 1 or by the system 202 of FIG. 2. With reference to FIG. 3B, there is further shown the ML model 210 and the set of batteries 302 including the first battery 302A, the second battery 302B, up to the Nth battery 302N. Each battery of the set of batteries 302 is an example embodiment of the battery 206 of FIG. 2. With reference to FIG. 3B, there is further shown a second set of features 314 associated with the set of batteries 302. Although illustrated with discrete blocks, the exemplary operations associated with one or more blocks of the block diagram 300B can be divided into additional blocks, combined into fewer blocks, or eliminated, depending on the implementation.

In an embodiment of the disclosure, the second set of features 314 includes at least one of a first feature associated with the potential difference between the first terminal and the second terminal of each battery of the set of batteries 302, a second feature associated with an aging model of each battery of the set of batteries 302, a third feature associated with a resistance of each battery of the set of batteries 302, a fourth feature associated with a charge capacity of each battery of the set of batteries 302, a fifth feature associated with the operating temperature of each battery of the set of batteries 302, or a sixth feature associated with an actual lifespan of each battery of the set of batteries 302.

In an embodiment of the disclosure, the first feature is associated with the potential difference between the first terminal and the second terminal of the battery at one or more historical timestamps. In an example embodiment of the disclosure, the potential difference at a first timestamp (when a battery is manufactured) is 20V, the potential difference at a second timestamp (after 6 months from the first timestamp) is 18V, and the potential difference at a third timestamp (after 12 months from the first timestamp) is 16V. In an embodiment of the disclosure, the system 202 obtains the potential difference at each of the one or more historical timestamps for training the ML model 210 for the prediction of the lifespan of the battery 206.

The aging model of each battery of the set of batteries 302 refers to a framework, which is used to predict and understand the degradation of battery performance of each battery of the set of batteries 302 over time. In an embodiment of the disclosure, the aging model describes the degradation of a battery based on the degradation of the charge storage capacity of the battery over time. In an example embodiment of the disclosure, the charge storage capacity of the battery at the first timestamp (when the battery is manufactured) is 4000 milli Ampere hour (mAh) and the charge storage capacity of the battery at a second timestamp (2 years after the first timestamp) is 3500 mAh.

The aging model describes the aging of each battery of the set of batteries 302 by calculating the capacity loss C_{loss,corr}(T, SOC, t) for each battery of the set of batteries 302 based on the equation (1):

$${C}_{loss , corr} ( T , SOC , t ) = \frac{{C}_{loss , corr} ( T , Soc ) * {C}_{loss , corr} ( T , t ) * {C}_{loss , corr , ϕ}}{{C}_{loss , corr} ( 50 \% Soc , t ) * {C}_{loss , corr} ( 40 ° C . , t )} \qquad ( 1 )$$

The numerator of equation (1) C_{loss,corr}(T, Soc)*C_{loss,corr}(T, t)*C_{loss,corr,ø} refers to the capacity loss of each battery of the set of batteries 302 over time at a specific temperature (T) and state of charge (SOC). The equation (1) further includes correction factors for temperature and state of charge deviations. These correction factors adjust the capacity loss based on differences from reference conditions (50% SOC and 40° C.). The denominator of equation (1) C_{loss,corr} (50% Soc, t)*C_{loss,corr}(40° C., t) involves the capacity loss of each battery of the set of batteries 302 at 50% state of charge deviations and 40 degrees Celsius, respectively, which serves as a baseline for corrections. The aging model helps in the prediction of the degradation of each battery of the set of batteries 302 under the conditions of different temperature values by adjusting for temperature and variations.

The resistance of each battery of the set of batteries 302 refers to a measure of the opposition to the flow of electric current offered by the corresponding battery. The resistance is obtained by taking a proportion of the potential difference associated with each battery at a timestamp to the amount of electric current flown through the corresponding battery during the corresponding timestamp. In an example embodiment of the disclosure, the resistance is, but is not limited to 20 milli ohms, 30 milli ohms, or 40 milli ohms.

The charge capacity of each battery of the set of batteries 302 refers to the amount of charge each battery holds when the corresponding battery is manufactured. In an example embodiment of the disclosure, the charge capacity of the battery is, but not limited to, 4000 mAh, 5000 mAh, or 5500 mAh. The operating temperature of each battery of the set of batteries refers to the temperature of each battery when the corresponding battery is operating. In an example embodiment of the disclosure, the operating temperature is, but not limited to, 35 degrees Celsius, 40 degrees Celsius, or 45 degrees Celsius.

The actual lifespan of each battery of the set of batteries 302 corresponds to the actual time period when the charge storage capacity of each battery of the set of batteries 302 tends to become less than the threshold charge capacity (say 80% of the charge storage capacity when the corresponding battery is manufactured). In an example embodiment of the disclosure, the actual lifespan may be, for example, 6 months, 1 year, 2 years, or the like.

At 316, a second set of features retrieval operation is performed. In an embodiment of the disclosure, the system 202 obtains the second set of features 314 associated with each battery of the set of batteries 302. The second set of features 314 is associated with the historical battery information of each battery of the set of batteries 302. In an embodiment of the disclosure, the historical battery information includes potential differences associated with each battery of the set of batteries 302 at one or more historical timestamps. The system 202 obtains the second set of features from each of the one or more sources 212.

At 318, a training dataset generation operation is performed. In an embodiment of the disclosure, the system 202 generates the training dataset based on the second set of features and the set of clusters 312. The system 202 generates the training dataset including input data and corresponding output data. The system 202 further generates the training dataset based on the second set of parameters corresponding to each cluster of the set of clusters 312. In an example embodiment of the disclosure, the system 202 generates the training dataset for each cluster of the set of clusters 312. The system 202 determines an average value (for each cluster) of each feature of the second set of features 314 corresponding to each battery in the corresponding cluster of the set of clusters 312.

In an embodiment of the disclosure, the input data includes one of a first parameter associated with the potential difference (average value for each cluster of the set of clusters 312), a second parameter associated with the aging model, a third parameter associated with the resistance, a fourth parameter associated with the charge capacity, or a fifth parameter associated with the operating temperature The corresponding output data includes an average actual lifespan of the one or more batteries in each cluster of the set of clusters 312. At 320, a machine learning training operation is performed. In an embodiment of the disclosure, the system 202 trains the ML model 210 based on the set of clusters and the training dataset. The system 202 provides the ML model 210 with the input data (one of the aging model, the potential difference, the resistance, the charge capacity, or the operating temperature) to predict the lifespan of the battery (say the specific battery) based on the input data. In an embodiment of the disclosure, the ML model 210 determines a mathematical relationship between the input data and the corresponding output data. The ML model 210 may further determine a machine learning algorithm for the prediction of the lifespan of each battery in the corresponding cluster of the set of clusters 312. The ML model 210 then uses the machine learning algorithm to predict the lifespan of each battery in the corresponding cluster of the set of clusters 312. The system 202 then determines an average predicted lifespan of each cluster of the set of clusters 312.

In an embodiment of the disclosure, the system 202 compares the average predicted lifespan of each cluster of the set of clusters 312 with the average actual lifespan of each cluster of the set of clusters 312 from the output data to determine a value of error. Thereafter, the system 202 adjusts the values of the weights and the regularization parameters associated with the neural network corresponding to the ML model 210 for minimizing the value of error (when the value tends towards zero and the average predicted lifespan is equal to the average actual lifespan). Then, the system 202 uses the ML model 210 to predict the lifespan of the battery based on the potential difference information.

In an embodiment of the disclosure, the system 202 trains the ML model 210 based on the set of clusters. The system 202 generates the first cluster of lithium-ion batteries and the second cluster of lead-acid batteries. Then, the system 202 trains the ML model 210 based on the first cluster of lithium-ion batteries and the second cluster of lead-acid batteries. The system 202 obtains the input data including one of the aging model, the potential difference, the resistance, the charge capacity, or the operating temperature of both the first cluster and the second cluster. Further, the system 202 provides the input data to the ML model 210 and similarly adjusts the weights and biases to minimize the error and therefore trains the ML model 210. Then, the system 202 uses the ML model 210 for the prediction of the lifespan of the batteries.

In an embodiment of the disclosure, the ML model corresponds to a multivariable polynomial regression model. The multivariable polynomial regression model uses a regression analysis process that predicts a dependent variable based on multiple independent variables using polynomial terms. The multivariable polynomial regression model is an extension of linear regression by incorporating polynomial relationships, allowing for more complex interactions between variables. By estimating coefficients for each term, the multivariable polynomial model can capture intricate patterns and interactions, providing a more accurate representation of the data.

In an exemplary embodiment of the disclosure, the ML model 210 predicts the lifespan of each battery of the set of batteries based on the application of the multivariable polynomial regression technique. The ML model 210 takes the input data (including one of the first parameter, the second parameter, the third parameter, the fourth parameter, and the fifth parameter) as the independent variable (in polynomial terms) and predicts the lifespan of the battery as the dependent variable based on estimating the coefficients of each term by capturing patterns and mathematical relationship between each feature of the second set of features 314 and the lifespan of each battery of the set of batteries 302.

FIG. 4 is a block diagram 400 that illustrates exemplary operations for prediction of lifespan of a battery, in accordance with an embodiment of the disclosure. FIG. 3B is explained in conjunction with elements from FIG. 1, FIG. 2, FIG. 3A and FIG. 3B. With reference to FIG. 4, there is shown the block diagram 400 that illustrates exemplary operations from 402 to 410, as described herein. The exemplary operations illustrated in the block diagram 400 start at 402 and are performed by any computing system, apparatus, or device, such as by the computer 102 of FIG. 1 or by the system 202 of FIG. 2. With reference to FIG. 3B, there is further shown the ML model 210. Although illustrated with discrete blocks, the exemplary operations associated with one or more blocks of the block diagram 400 can be divided into additional blocks, combined into fewer blocks, or eliminated, depending on the implementation.

At 402, a battery information retrieval operation is performed. In an embodiment of the disclosure, the system 202 retrieves the potential difference information indicating the potential difference between the first terminal 208A of the battery 206 (or the specific battery) and the second terminal 208B of the battery 206 (or the specific battery). The system 202 retrieves the battery information from the one or more sources 212. In an embodiment of the disclosure, the system 202 receives the battery information associated with the battery 206 from the user device 214 associated with the electronic device 204.

In an alternate embodiment of the disclosure, the system 202 retrieves the potential difference between the first terminal 208A of the battery 206 and the second terminal 208B of the battery 206 from the voltmeter associated with the electronic device 204. In an alternate embodiment of the disclosure, the system 202 retrieves the battery information (or the potential difference) from the first terminal 208A and the second terminal 208B of the battery 206.

In an embodiment of the disclosure, the battery information associated with the specific battery further includes battery composition information, battery vendor information, battery usage environment information, or battery age information. The battery composition information includes the information associated with the chemical composition of the electrolyte of the battery 206. In an example embodiment of the disclosure, the battery 206 is one of, but not limited to, a lithium-ion battery, a lead-acid battery, a non-lithium battery, a nickel metal hydride (NiMH) battery, an Absorbent Glass Mat (AGM) battery, an Enhanced Flooded Battery (EFB), or the like based on the battery composition information.

The battery vendor information includes the information associated with the vendor (or a manufacturer) of the battery 206. In an example embodiment of the disclosure, the vendor of the specific battery is one of, for example, but not limited to ABC Energy Savings, XYZ Solutions, or PQR Energy Solutions. The battery usage environment information includes the information associated with the operating temperature of the specific battery (or the battery 206). In an example embodiment of the disclosure, the operating temperature of the battery 206 is one of, but not limited to, 35 degrees Celsius, 40 degrees Celsius, and 45 degrees Celsius. The battery age information includes the information associated with the age of the battery 206. The age of the battery is one of, for example, but not limited to, less than 1 year, 2 years, or greater than 2 years.

At 404, a machine learning (ML) application operation is performed. In an embodiment of the disclosure, the system 202 applies the ML model 210 on the battery information. The ML model 210 is trained to predict the lifespan of the battery 206. The lifespan of the battery 206 corresponds to the time period until the charge storage capacity of the battery 206 is above the threshold charge capacity. In an example embodiment of the disclosure, the threshold charge capacity of the battery 206 is 80% of the charge storage capacity when the battery 206 is manufactured.

In an embodiment of the disclosure, the ML model 210 takes the first timestamp (when the system 202 determines the lifespan of the battery 206) as the reference and predicts the second timestamp (when the charge storage capacity of the battery 206 is just lesser than 80% of the charge storage capacity of the battery 206 at the first timestamp) as the output based on the battery information. In an example embodiment of the disclosure, the ML model predicts that the lifespan of the battery is until, for example, “1 Apr. 2024” (the second timestamp) when the current date is “1 Jan. 2024” (the first timestamp).

In an example embodiment of the disclosure, the ML model compares the retrieved potential difference (for example 18V) with a reference potential difference (when the battery 206 is manufactured, for example, 20V) associated with the battery 206. The ML model 210 further predicts the lifespan (the second timestamp) at which the charge storage capacity tends to be just less than the threshold charge capacity of the battery 206 based on the comparison.

At 406, a lifespan information determination operation is performed. In an embodiment of the disclosure, the system 202 determines the lifespan information based on the application of the ML model 210 on the battery information. The lifespan information is indicative of the lifespan of the specific battery. The system 202 determines the lifespan information associated with the specific battery based on the output generated by the application of the ML model 210 on the battery information. The lifespan information includes, for example, the lifespan of the specific battery and optionally, a recommendation for replacement of the specific battery.

In an example embodiment of the disclosure, the system 202 determines the lifespan information based on calculating the time period between the first timestamp (when the system 202 is used to determine the lifespan information) and the second timestamp (predicted by the ML model 210). The system 202 determines the lifespan information that the lifespan of the specific battery is, for example, 3 months from the current date (the date on which the system 202 determines the lifespan information) and the recommendation to replace the specific battery before 3 months.

At 408 a lifespan information rendering operation is performed. In an embodiment of the disclosure, the system 202 renders the determined lifespan information. In an embodiment of the disclosure, the system 202 renders the determined lifespan information including the lifespan of the specific battery which is predicted by the ML model 210 and the recommendation. In an embodiment of the disclosure, the system 202 renders the determined lifespan information on the display of the user device 214. In an alternate embodiment of the disclosure, the system 202 renders the lifespan information on the display of the electronic device 204.

In an example embodiment of the disclosure, the system 202 renders the lifespan information indicating that the lifespan of the battery 206 is three months from the current date (the date on which the system 202 predicts the lifespan of the battery 206) and optionally the recommendation to replace the battery 206 within three months. In addition to this, further details about the lifespan information rendering operation are provided in, for example, FIG. 6A and FIG. 6B.

At 410, a feedback reception operation is performed. In an embodiment of the disclosure, the system 202 receives feedback associated with the lifespan of the battery 206 from the user device 214. The system 202 receives the feedback from the user 216 via the user device 214 based on the predicted lifespan of the battery 206. The system 202 receives positive feedback (that the prediction turns out to be correct) based on when the predicted lifespan of the battery 206 is equal to the actual lifespan of the battery 206. In an example embodiment of the disclosure, the system 202 predicts that the lifespan of the battery 206 is 3 months from a current date, and the actual lifespan of the battery 206 is 3 months, then the system 202 receives the positive feedback from the user device 214.

In an alternate embodiment of the disclosure, the system 202 receives negative feedback (that the prediction turns out to be incorrect) based on when the predicted lifespan of the battery 206 is not equal to the actual lifespan of the battery 206. In an example embodiment of the disclosure, the system 202 predicts the lifespan of the battery 206 is 6 months, but the actual lifespan of the battery is less than 6 months (say 3 months), or the actual lifespan is more than 6 months (say 10 months), then in both these scenarios, the system 202 receives the negative feedback from the user device 214.

At 320, the ML model training operation is performed. In an embodiment of the disclosure, the system 202 trains (or re-trains) the ML model 210 based on the feedback. The system 202 adjusts the weights and the regularization parameters based on the negative feedback. The system 202 adjusts the weights and the regularization parameters of the neural network corresponding to the ML model 210 to minimize the value of error between the predicted lifespan and the actual lifespan of the corresponding battery. In an alternate embodiment of the disclosure, the system 202 reinforces the weights and the regularization parameters in case of the positive feedback. The system 202 performs the re-training based on the feedback to fine-tune the ML model 210 to ensure that the predicted lifespan of the battery 206 is equal to the actual lifespan of the battery 206. Such re-trained ML model 210 may be stored and used to predict the lifespan of the batteries in the future. In an embodiment of the disclosure, the system 202 may adjust the weights and the regularization parameters associated with the ML model 210 based on one of the negative feedback or the positive feedback using a back-propagation technique. Details about the back-propagation technique are known in the art and have been omitted from the description for the sake of brevity.

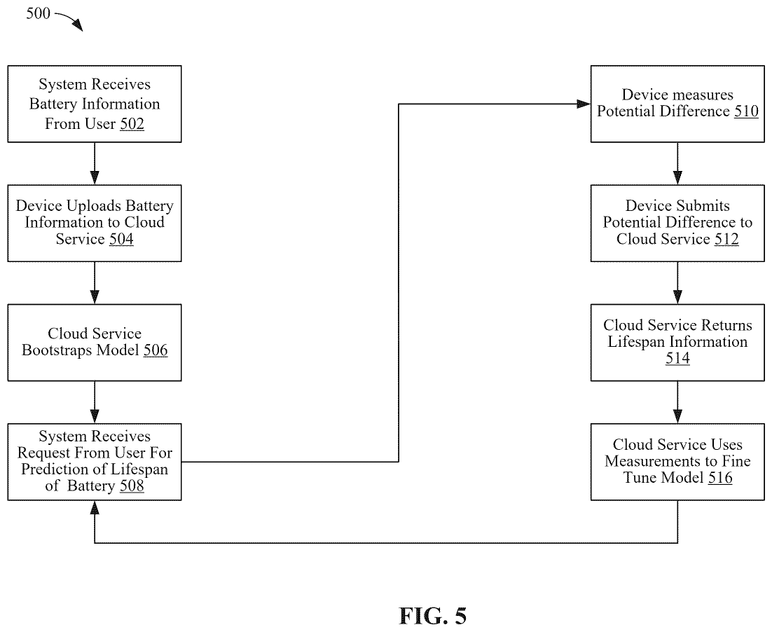

FIG. 5 is a schematic diagram 500 that illustrates exemplary steps for prediction of lifespan of a battery, in accordance with an embodiment of the disclosure. FIG. 5 is explained in conjunction with elements from FIG. 1, FIG. 2, FIG. 3A, FIG. 3B and FIG. 4. With reference to FIG. 5, there is shown the schematic diagram 500 that illustrates exemplary operations from 502 to 516, as described herein. The exemplary steps illustrated in the schematic diagram 500 starts at 502 and are performed by any computing system, apparatus, or device, such as by the computer 102 of FIG. 1 or by the system 202 of FIG. 2.

In an embodiment of the disclosure, the system 202 may be embodied as a cloud-based service, a cloud-based application, a cloud-based platform, a remote server-based service, a remote server-based application, a remote server-based platform, or a virtual computing system as described in FIG. 1 and FIG. 2.

At 502, the battery information associated with the specific battery (or the battery 206) is received from the user 216. In an embodiment of the disclosure, the system 202 receives the battery information from the user 216 via the user device 214. The battery information associated with the specific battery includes information associated with at least one of the composition of the specific battery (the battery 206), the vendor of the battery 206, the operating temperature of the battery 206, or the age of the battery 206. Details about the battery information retrieval operation are provided, for example, in FIG. 4.

At 504, the battery information is uploaded to the cloud by the user device 214. In an embodiment of the disclosure, the system 202 corresponds to the cloud (or the cloud-based service) that receives the battery information from the user device 214. The user device 214 uploads the battery information to the cloud-based service for further processing and determination of the lifespan information.

At 506, the cloud based service bootstraps the ML model 210. In an embodiment of the disclosure, the system 202 (or the cloud-based service) bootstraps the ML model 210. The system 202 performs the bootstrapping of the ML model 210 by employing a resampling technique, which involves repeatedly generating a set of random samples of the training dataset for training the ML model 210 with replacement from the original training dataset to generate a set of new training datasets. The bootstrapping of the ML model 210 may help in estimating the accuracy and stability of the ML model 210 by generating one or more training scenarios. Each bootstrapped sample of the set of random samples is used to train the ML model 210, and the result of each training is aggregated to make the ML model 210 more robust and less prone to overfitting. Details about bootstrapping of the ML model are known in the art and therefore have been omitted for the sake of brevity.

At 508, the system 202 (or the cloud-based service) receives the request for prediction of the lifespan of the battery 206 from the user 216 via the user device 214. Details about the lifespan information determination operation are provided, for example, in FIG. 4. At 510, the potential difference is measured by the electronic device 204. In an embodiment of the disclosure, the system 202 receives the potential difference between the first terminal 208A and the second terminal 208B of the battery 206 from the electronic device 204. At 512, the potential difference measurement may be submitted to the system 202 (or the cloud-based service). The system 202 (or the cloud-based service) receives the potential difference between the first terminal 208A and the second terminal 208B of the battery 206 from the electronic device 204. Details about the battery information retrieval operation are provided, for example, in FIG. 1 and FIG. 4.

At 514, the cloud service returns the determined lifespan information. In an embodiment of the disclosure, the system 202 applies the ML model 210 on the battery information including the potential difference information. The ML model 210 is trained to determine the lifespan of the specific battery (the battery 206). Details about the training of the ML model are provided, for example, in FIG. 3A and FIG. 3B.

Further, the system 202 determines the lifespan information based on the application of the ML model 210 on the battery information. Details about the lifespan information determination operation are provided, for example, in FIG. 4. The lifespan information is indicative of the lifespan of the battery 206). Further, the system 202 renders the lifespan information on the user device 214. Details about the lifespan information rendering operation are provided, for example, in FIG. 4, FIG. 6A and FIG. 6B.

At 516, the cloud service uses measurement to fine-tune the ML model 210. The system 202 (or the cloud-based service) uses the potential difference to fine-tune the ML model 210. The system 202 further receives feedback from the user 216 via the user device 214 for fine-tuning the ML model 210. Once the ML model 210 is fine-tuned based on the feedback from the user 216, the fine-tuned ML model 210 may be stored in one of the volatile memory 118 or the persistent storage 120. At a future timestamp (i.e. after a current timestamp), if the system 202 received a new request prediction of the lifespan of a new battery, then the system 202 may utilize the fine-tuned ML model 210 to predict the lifespan of the new battery indicated by the link between 508 and 516. Details about the feedback retrieval operation and the ML model training operation are provided, for example, in FIG. 4.

FIG. 6A is a diagram that depicts an exemplary first user interface for prediction of lifespan of a battery, in accordance with an embodiment of the disclosure. FIG. 6A is explained in conjunction with elements from FIG. 1, FIG. 2, FIG. 3A, FIG. 3B, FIG. 4 and FIG. 5. With reference to FIG. 6A, there is shown an exemplary diagram 600A that includes a user device 602 and an exemplary input page 604 that may include a first user interface (UI) element 606, a second UI element 606A, a third UI element 606B, a fourth UI element 606C, and a fifth UI element 608. The user device 602 is an example embodiment of the electronic device 204 and the user device 214 of FIG. 1.

With reference to FIG. 6A, the system 202 receives the battery information from the user 216 via the user device 602. The user device 602 includes the display that renders the input page 604 to the user 216. The system 202 renders the input page 604 on a user interface (UI) of the user device 602. The input page 604 corresponds to a web page or online form that is designed to collect information from entities (or users) who wish to determine the lifespan of batteries associated with their electronic devices. In an embodiment of the disclosure, the input page 604 is used to gather relevant details from the user 216 to predict the lifespan of the battery 206.

The first UI element 606 corresponds to a textbox that includes a message for the user 216, for example, “Enter Battery Information”. The first UI element 606 further includes the second UI element 606A, the third UI element 606B, and the fourth UI element 606C. The second UI element 606A corresponds to a textbox where the user 216 (or the entities) provides the potential difference information (the potential difference between the first terminal 208A and the second terminal 208B of the battery 206). In an embodiment of the disclosure, the second UI element 606A is a mandatory input parameter that needs to be provided for the prediction of the lifespan of the battery 206.

The third UI element 606B corresponds to a button and is labeled as “Auto Capture Potential Difference”. In an embodiment of the disclosure, upon selecting the third UI element, the system 202 automatically retrieves the potential difference from the voltmeter associated with the electronic device 204. In an exemplary embodiment of the disclosure, the third UI element will be unresponsive (or unavailable) when the system 202 (or the electronic device 204) is not directly associated (or physically attached with the help of connecting wires) with the voltmeter. In that scenario, the user 216 manually provides the potential difference via the second UI element 606A (in a scenario when the user 216 uses the user device 214).

After providing the potential difference, the user 216 may wish to provide further information associated with the battery 206 via the fourth UI element 606C. The fourth UI element 606C corresponds to a textbox which includes a first message (for example “Battery Type”) for inputting the composition of the battery 206. The fourth UI element 606C further includes a first checkbox associated with the lithium-ion batteries, a second checkbox associated with the lead-acid batteries, a third checkbox associated with the nickel-metal hydride batteries, and a fourth checkbox if the composition of the battery 206 is either not-known or is other than these three types. The system 202 receives the information associated with the composition of the battery 206 (the battery composition information) based on a selection of one of the first checkbox, the second checkbox, the third checkbox, or the fourth checkbox by the user 216.

Further, the fourth UI element 606C includes a second message (for example “Vendor”) for inputting the vendor of the battery 206. The fourth UI element 606C includes a fifth checkbox associated with for example ABC Energy Savings, a sixth checkbox associated with for example XYZ Solutions, a seventh checkbox associated with for example PQR Energy Solutions, and an eighth checkbox if the vendor of the battery 206 is either not known or is other than these three types. The system 202 receives the information associated with the vendor of the battery (the battery vendor information) based on a selection of one of the fifth checkbox, the sixth checkbox, the seventh checkbox, or the eighth checkbox by the user 216.

Further, the fourth UI element 606C includes a third message (for example “Operating Temperature”) for inputting the operating temperature (the battery usage environment information) of the battery 206. The fourth UI element 606C includes a ninth checkbox associated with if the battery is operating at room temperature (for example 30 degree Celsius), and a tenth checkbox associated with if the battery is operating at a temperature other than room temperature. The system 202 receives the information associated with the operating temperature of the battery 206 (the battery usage environment information) based on a selection of one of the ninth checkbox or the tenth checkbox by the user 216.

Further, the fourth UI element 606C includes a fourth message (for example “Battery Age Information”) for inputting the age information of the battery 206. The fourth UI element 606C includes an eleventh checkbox associated with if the battery is less than 1 year in use, a twelfth checkbox associated with if the battery is around 2 years of use, and a thirteenth checkbox associated with if the battery is more than 2 years of use. The system 202 receives the information associated with the age of the battery 206 (the battery age information) based on a selection of one the eleventh checkbox, the twelfth checkbox, or the thirteenth checkbox by the user 216. The fifth UI element 608 corresponds to a button and is labeled as “Submit”. Upon selecting the fifth UI element 608, the system 202 receives the input and further initiates the prediction of the lifespan of the battery 206.

FIG. 6B is a diagram that depicts an exemplary second user interface for prediction of lifespan of a battery, in accordance with an embodiment of the disclosure. FIG. 6B is explained in conjunction with elements from FIG. 1, FIG. 2, FIG. 3A, FIG. 3B, FIG. 4, FIG. 5, and FIG. 6A. With reference to FIG. 6B, there is shown an exemplary diagram 600B that includes the user device 602 and an exemplary output page 610 that may include a sixth UI element 612 and a seventh UI element 614. The user device 602 is an example embodiment of the electronic device 204 and the user device 214 of FIG. 1.

With reference to FIG. 6B, the system 202 renders the output page 610 on the display of the user device 602 based on when the system 202 determines the lifespan information. The system 202 renders the determined lifespan information on the output page 610. The output page 610 corresponds to a webpage that is designed to provide information associated with the lifespan of the battery 206. The output page 610 provides the information associated with the lifespan of the battery 206 to the user 216.

The sixth UI element 612 corresponds to a textbox that includes a message associated with the lifespan of the battery 206. In an example embodiment of the disclosure, the message includes the lifespan of the battery 206, for example, “Battery Analysis: System Detected that the lifespan of the battery will be over in upcoming 3 months.”.

The seventh UI element 614 corresponds to a textbox that includes a recommendation associated with the replacement of the specific battery. In an example embodiment of the disclosure, the recommendation includes a message, for example, “Urgent replacement of the battery is recommended within the upcoming 3 months. It is recommended to use a lithium-ion battery instead of a lead-acid battery as the lithium-ion battery has a longer lifespan”.

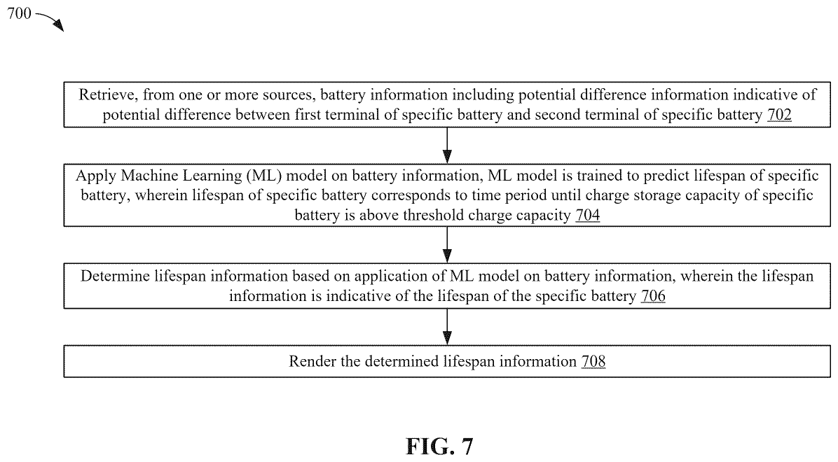

FIG. 7 is a flowchart that illustrates an exemplary method for prediction of lifespan of a battery, in accordance with an embodiment of the disclosure. FIG. 7 is explained in conjunction with elements from FIG. 1, FIG. 2, FIG. 3A, FIG. 3B, FIG. 4, FIG. 5, FIG. 6A, and FIG. 6B. With reference to FIG. 7, there is shown a flowchart 700. The operations of the exemplary method may be executed by any computing system, for example, by the computer 102 of FIG. 1 or the system 202 of FIG. 2. The operations of the flowchart 700 may start at 702.

At 702, the battery information including the potential difference information indicative of the potential difference between the first terminal 208A of the specific battery (the battery 206) and the second terminal 208B of the specific battery (the battery 206) is retrieved from one or more sources 212. In an embodiment of the disclosure, the system 202 retrieves the potential difference information indicating the potential difference between the first terminal 208A of the specific battery (the battery 206) and the second terminal 208B of the specific battery (the battery 206). The system 202 retrieves the battery information from the one or more sources 212. Details about the battery information retrieval operation are provided in FIG. 4.

At 704, the ML model 210 is applied on the battery information. The ML model 210 is trained to predict the lifespan of the specific battery (the battery 206). The lifespan of the specific battery (the battery 206) corresponds to the time period until the charge storage capacity of the specific battery (the battery 206) is above the threshold charge capacity. In an embodiment of the disclosure, the system 202 applies the ML model 210 on the battery information. The ML model 210 is trained to predict the lifespan of the specific battery (the battery 206). The lifespan of the specific battery (the battery 206) corresponds to the time period until the charge storage capacity of the specific battery (the battery 206) is above the threshold charge capacity. Details about the machine learning application operation are provided in FIG. 4.

At 706, the lifespan information is determined based on the application of the ML model 210 on the battery information. The lifespan information indicates the lifespan of the specific battery. In an embodiment of the disclosure, the system 202 determines the lifespan information based on the application of the ML model 210 on the battery information. The lifespan information indicates the lifespan of the specific battery (the battery 206). Details about the lifespan information determination operation are provided in FIG. 4.

At 708, the lifespan information is rendered. In an embodiment of the disclosure, the system 202 renders the lifespan information. Details about the lifespan information rendering operation are provided in FIG. 4.

Various embodiments of the disclosure may provide a non-transitory computer readable medium and/or storage medium having stored thereon, instructions executable by a machine and/or a computer to operate a system (e.g., the system 202) for prediction of the lifespan of a battery. The instructions may cause the machine and/or computer to perform operations that include retrieving battery information including potential difference information indicative of a potential difference between a first terminal of the battery and a second terminal of the battery. The battery information is retrieved from one or more sources. The operations further include applying a machine learning (ML) model on the battery information. The ML model is trained to predict the lifespan of the battery. The lifespan of the battery corresponds to a time period until a charge storage capacity of the battery is above a threshold charge capacity. The operations further include determining the lifespan of the battery based on the application of the ML model on the battery information. The operations further include rendering a message including at least the lifespan of the battery.

The descriptions of the various embodiments of the disclosure have been presented for purposes of illustration but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein.

What is claimed is:

1. A computer-implemented method, comprising:
retrieving, by a computer, from one or more sources, battery information comprising potential difference information indicative of a potential difference between a first terminal of a specific battery and a second terminal of the specific battery;
applying, by the computer, a machine learning (ML) model on the battery information, the ML model is trained to predict a lifespan of the specific battery, wherein the lifespan of the specific battery corresponds to a time period until a charge storage capacity of the specific battery is above a threshold charge capacity;
determining, by the computer, lifespan information based on the application of the ML model on the battery information, wherein the lifespan information is indicative of the predicted lifespan of the specific battery; and
rendering, by the computer, the determined lifespan information.

2. The computer-implemented method of claim 1, wherein the battery information associated with the specific battery further comprises at least one of battery composition information, battery vendor information, battery usage environment information, or battery age information.

3. The computer-implemented method of claim 1, further comprising:
obtaining, by the computer, a first set of features associated with each battery of a set of batteries, wherein the specific battery is excluded from the set of batteries; and
applying, by the computer, a clustering technique on the first set of features associated with each battery of the set of batteries to generate a set of clusters associated with at least a composition of each battery of the set of batteries.

4. The computer-implemented method of claim 3, wherein the first set of features comprises at least one of a first feature associated with the composition of each battery of the set of batteries, a second feature associated with a vendor of each battery of the set of batteries, a third feature associated with a voltage of each battery of the set of batteries, a fourth feature associated with a voltage per cell of each battery of the set of batteries, a fifth feature associated with a nominal charge capacity of each battery of the set of batteries, a sixth feature associated with an energy density of each battery of the set of batteries, a seventh feature associated with an operating temperature range of each battery of the set of batteries, or an eighth feature associated with dimensions of each battery of the set of batteries.

5. The computer-implemented method of claim 3, further comprising:
obtaining, by the computer, a second set of features associated with each battery of the set of batteries;
generating, by the computer, a training dataset based on the second set of features; and
training, by the computer, the ML model based on the set of clusters and the training dataset.

6. The computer-implemented method of claim 5, wherein the second set of features further comprises at least one of a first feature associated with the potential difference between the first terminal and the second terminal of each battery of the set of batteries, a second feature associated with an aging model of each battery of the set of batteries, a third feature associated with a resistance of each battery of the set of batteries, a fourth feature associated with a charge capacity of each battery of the set of batteries, a fifth feature associated with an operating temperature of each battery of the set of batteries, or a sixth feature associated with an actual lifespan of each battery of the set of batteries.

7. The computer-implemented method of claim 1, wherein the ML model corresponds to a multivariable polynomial regression model.

8. The computer-implemented method of claim 1, further comprising:
receiving, by the computer, from a user device, feedback associated with the lifespan of the specific battery; and
training, by the computer, the ML model based on the feedback.

9. A system, comprising:
a processor set configured to:
retrieve, from one or more sources, battery information comprising potential difference information indicative of a potential difference between a first terminal of a specific battery and a second terminal of the specific battery;
apply a machine learning (ML) model on the battery information, the ML model is trained to predict a lifespan of the specific battery, wherein the lifespan of the specific battery corresponds to a time period until a charge storage capacity of the specific battery is above a threshold charge capacity;
determine lifespan information based on the application of the ML model on the battery information, wherein the lifespan information is indicative of the predicted lifespan of the specific battery; and
render the determined lifespan information.

10. The system of claim 9, wherein the battery information associated with the specific battery further comprises at least one of battery composition information, battery vendor information, battery usage environment information, or battery age information.

11. The system of claim 9, wherein the processor set is further configured to:
obtain a first set of features associated with each battery of a set of batteries, wherein the specific battery is excluded from the set of batteries; and
apply a clustering technique on the first set of features associated with each battery of the set of batteries to generate a set of clusters associated with at least a composition of each battery of the set of batteries.

12. The system of claim 11, wherein the first set of features comprises at least one of a first feature associated with the composition of each battery of the set of batteries, a second feature associated with a vendor of each battery of the set of batteries, a third feature associated with a voltage of each battery of the set of batteries, a fourth feature associated with a voltage per cell of each battery of the set of batteries, a fifth feature associated with a nominal charge capacity of each battery of the set of batteries, a sixth feature associated with an energy density of each battery of the set of batteries, a seventh feature associated with an operating temperature range of each battery of the set of batteries, or an eighth feature associated with dimensions of each battery of the set of batteries.

13. The system of claim 11, wherein the processor set is further configured to:
obtain a second set of features associated with each battery of the set of batteries;
generate a training dataset based on the second set of features; and
train the ML model based on the set of clusters and the training dataset.

14. The system of claim 13, wherein the second set of features further comprises at least one of a first feature associated with the potential difference between the first terminal and the second terminal of each battery of the set of batteries, a second feature associated with an aging model of each battery of the set of batteries, a third feature associated with a resistance of each battery of the set of batteries, a fourth feature associated with a charge capacity of each battery of the set of batteries, a fifth feature associated with an operating temperature of each battery of the set of batteries, or a sixth feature associated with an actual lifespan of each battery of the set of batteries.

15. The system of claim 9, wherein the ML model corresponds to a multivariable polynomial regression model.

16. The system of claim 9, wherein the processor set is further configured to:
receive, from a user device, feedback associated with the lifespan of the specific battery; and
train the ML model based on the feedback.

17. A computer program product for prediction of a lifespan of a specific battery, the computer program product comprising a computer-readable storage medium having program instructions embodied therewith, the program instructions executable by a system to cause the system to:
retrieve, from one or more sources, battery information comprising potential difference information indicative of a potential difference between a first terminal of the specific battery and a second terminal of the specific battery;
apply a machine learning (ML) model on the battery information, the ML model is trained to predict the lifespan of the specific battery, wherein the lifespan of the specific battery corresponds to a time period until a charge storage capacity of the specific battery is above a threshold charge capacity;
determine lifespan information based on the application of the ML model on the battery information, wherein the lifespan information is indicative of the lifespan of the specific battery; and
render the determined lifespan information.

18. The computer program product of claim 17, wherein the battery information associated with the specific battery further comprises at least one of battery composition information, battery vendor information, battery usage environment information, or battery age information.

19. The computer program product of claim 17, wherein the program instructions further cause the system to:
obtain a first set of features associated with each battery of a set of batteries, wherein the specific battery is excluded from the set of batteries; and
apply a clustering technique on the first set of features associated with each battery of the set of batteries to generate a set of clusters associated with at least a composition of each battery of the set of batteries.

20. The computer program product of claim 19, wherein the program instructions further cause the system to:
obtain a second set of features associated with each battery of the set of batteries;
generate a training dataset based on the second set of features; and
train the ML model based on the set of clusters and the training dataset.
